(19) United States
(12) Patent Application Publication
(10) Pub. No.: US 2015/0077889 A1
(43) Pub. Date: Mar. 19, 2015

(54) PROTECTIVE DEVICE

(71) Applicant: George M. Kauffman, Hudson, MA (US)

(72) Inventor: George M. Kauffman, Hudson, MA (US)

(21) Appl. No.: 14/486,153

(22) Filed: Sep. 15, 2014

Related U.S. Application Data
(60) Provisional application No. 61/877,719, filed on Sep. 13, 2013.
(60) Provisional application No. 61/954,778, filed on Mar. 18, 2014.

(51) Int. Cl. H02H 9/04; H03H 7/01; H02H 9/00

(52) U.S. Cl. CPC H02H 9/045; H02H 9/005; H03H 7/17
USPC 361/56

(57) ABSTRACT

A device designed to protect low-voltage circuits includes a transmission line for transmitting electromagnetic signals of an operational frequency band, a capacitor located in series on the transmission line, and a diode-based clamping component connecting the transmission line to ground. In use, the capacitor is designed to filter any unwanted transient energy that falls beneath the operational frequency band and the clamping component is designed to limit unwanted transient energy that falls within the operational frequency band. A gas discharge tube (GDT) connecting the transmission line to ground preferably protects low-voltage circuits from higher current threats. An inductive component constructed of a ferrite material, such as a ferrite bead, is connected in series with the GDT. Upon activation of the GDT, the inductive component manages the fall time of the GDT and thereby prevents the output waveform generated in response to GDT activation from shifting into the operational frequency band.

### FIELD OF THE INVENTION

The present invention relates generally to devices for transmitting electromagnetic signals of a desired frequency range and, more particularly, to devices for transmitting electromagnetic signals of a desired frequency range that additionally provide overvoltage protection to the transmission line.

### BACKGROUND OF THE INVENTION

A transmission line, or signal path, is a structure designed to efficiently transmit electromagnetic signals, such as radio frequency (RF) signals, from a signal source to a load. The transmission line formed between the signal source and the load is commonly established using one or more electric devices, such as coaxial cables, connectors and switches.

Electric devices of the type described above are well known in the art and are widely used to transmit electromagnetic signals over 10 MHz with minimum loss and limited distortion. As a result, these types of electric devices are commonly used to transmit and receive signals in telecommunications, broadcast, military, security and civilian transceiver applications, as well as numerous additional uses.

Electric devices used to transmit electromagnetic signals are often provided with means for protecting the load from any potentially harmful, transient, high-voltage electromagnetic energy present along the transmission line (e.g., as the result of a lightning strike or electro-static discharge). In particular, electric devices with overvoltage protection, referred to herein simply as protective devices, are particularly needed for loads that include voltage sensitive circuitry that operates at a frequency range above approximately 10 MHz, such as radio receivers, low-voltage control circuits and low-voltage communication circuits.

It has been found that low-voltage circuits of the type described above are susceptible to a wide variety of different destructive energy including, but not limited to, (i) oscillating ring waves with a frequency between 10 kHz and 100 MHz, and (ii) impulses with a rise time of approximately 1 ns or more and a pulse width in the range from 30 ns to 500 microseconds, both types of energy having a peak current that ranges between a few amperes to a few tens of amperes. Generally, the lower frequency energy is more destructive to the low-voltage circuit, since the lower frequency energy exists for longer durations and the fundamental frequency of impulses is commonly of the highest spectral content.

For low-voltage circuits connected to a transmission line operating at a frequency range above approximately 10 MHz, it has been found that most of the destructive transient energy falls below the operational frequency band. This energy that falls below operational frequency band is often blocked using conventional circuit protection techniques.

For example, protective devices commonly rely upon gas discharge tubes (GDTs) and/or shunting components to treat undesirable, below operational frequency, electromagnetic energy that is present along the transmission line.

Although gas discharge tubes can operate over a wide range of frequencies (even well over 1 GHz) and can exhibit very high transient current shunting capabilities, gas discharge tubes respond too slowly to fast rise time transients. For example, when destructive electromagnetic energy with 5 KV/microsecond edge rates is present on the transmission line, a 90 volt nominal gas discharge tube will pass through to the load a 600 volt impulse that last for about 100 ns. Moreover, faster pulses will pass through to the load an even higher transient impulse. This high-voltage residual pulse passed through the transmission line by the gas discharge tube is substantial enough to permanently damage sensitive electrical equipment.

Shunting protectors, which are incorporated into protective devices to shunt to ground undesirable electromagnetic energy present along the transmission line, are typically provided in the form of a quarter wave shunt or an inductor.

Quarter wave shunts, or stubs, have been found to be particularly effective in applications with an operational frequency range of over 500 MHz. In fact, the higher the operational frequency of the application, the more efficient the quarter wave shunt becomes at removing the undesirable energy from the transmission line. However, it has been found that quarter wave shunts are ineffective in passing frequencies below 400 MHz, and therefore are not generally utilized in signal transmission applications with a lower operational frequency range.

Similarly, inductors utilized to shunt undesirable energy from the transmission line suffer from certain performance limitations. Specifically, inductors can only be incorporated into protective devices that operate at frequencies below 100 MHz and, in addition, have been found to experience severe limitations in removing fast rise time transients.

Although both types of shunting protectors described in detail above are commonly utilized in the art to treat electromagnetic energy that falls beneath the operational frequency band, it has been found that the aforementioned shunting protectors are not similarly capable of providing significant attenuation of potentially destructive energy that falls within the operational frequency band. As a result, destructive transient energy that falls within the operational frequency band poses a significant risk to relatively sensitive, low-voltage circuits coupled to the signal path. In fact, most conventional protection devices have been found to be incapable of limiting, or otherwise treating, transient energy that falls both below and within the operational frequency band without compromising the quality of the desired electrical energy (i.e., the desired signal that falls within the operational frequency band).

### SUMMARY OF THE INVENTION

It is an object of the present invention to provide a new and improved protective device for transmitting electromagnetic signals of a desired frequency band.

It is another object of the present invention to provide a protective device of the type as described above that is designed to treat any potentially harmful, transient, high-voltage electromagnetic energy present on the transmission line.

It is yet another object of the present invention to provide a protective device of the type as described above that is particularly well suited for use in protecting a low-voltage circuit in electrical communication with the transmission line from the transient electromagnetic energy.

It is still another object of the present invention to provide a protective device of the type as described above that is effective in treating transient electromagnetic energy that falls both below and within the operational frequency band without compromising the quality of the desired electrical energy.

It is yet still another object of the present invention to provide a protective device of the type as described above that has a limited number of parts, is inexpensive to manufacture and is easy to use.

Accordingly, as a feature of the present invention, there is provided a protective device for transmitting electromagnetic signals of an operational frequency band, the protective device comprising (a) a transmission line connecting an input terminal to an output terminal, (b) a filter for blocking any transient electromagnetic energy received by the transmission line that has a frequency that falls below the operational frequency band, the filter comprising a capacitor located in series on the transmission line between the input terminal and the output terminal, and (c) a semiconductor-based clamping component for limiting any transient electromagnetic energy received at the input terminal that has a frequency that falls within the operational frequency band, the semiconductor-based clamping component connecting the transmission line to a ground terminal, the semiconductor-based clamping component being connected to the transmission between the capacitor and the output terminal.

Various other features and advantages will appear from the description to follow. In the description, reference is made to the accompanying drawings which form a part thereof, and in which is shown by way of illustration, various embodiments for practicing the invention. The embodiments will be described in sufficient detail to enable those skilled in the art to practice the invention, and it is to be understood that other embodiments may be utilized and that structural changes may be made without departing from the scope of the invention. The following detailed description is therefore, not to be taken in a limiting sense, and the scope of the present invention is best defined by the appended claims.

### BRIEF DESCRIPTION OF THE DRAWINGS

In the drawings wherein like reference numerals represent like parts:

FIG. 1 is a front perspective view of a first embodiment of a protection device constructed according to the teachings of the present invention;

FIG. 2 is a front perspective view of the protection device shown in FIG. 1, the protection device being shown with the cover removed therefrom;

FIG. 3 is a schematic representation of the electrical circuit shown in FIG. 2;

FIG. 4 is a front perspective view of a second embodiment of a protection device constructed according to the teachings of the present invention, the protection device being shown with the cover removed therefrom;

FIG. 5 is a schematic representation of the electrical circuit shown in FIG. 4;

FIG. 6 is a front perspective view of a third embodiment of a protection device constructed according to the teachings of the present invention, the protection device being shown with the cover removed therefrom;

FIG. 7 is a schematic representation of the electrical circuit shown in FIG. 6;

FIG. 8 is a front perspective view of a fourth embodiment of a protection device constructed according to the teachings of the present invention, the protection device being shown with the cover removed therefrom; and

FIG. 9 is a schematic representation of the electrical circuit shown in FIG. 8.

### DETAILED DESCRIPTION OF THE INVENTION

### Construction of Protective Device 11

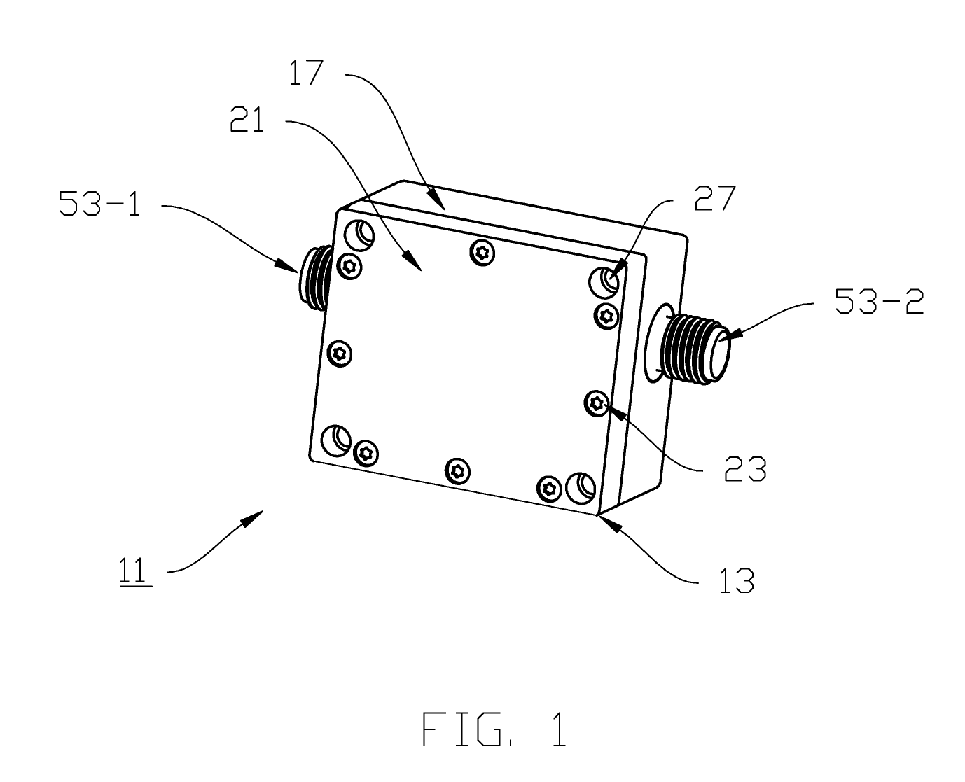

Referring now to FIGS. 1-3, there is shown a protective device for transmitting electromagnetic signals of a desired frequency range, the protective device being constructed according to the teachings of the present invention and identified generally by reference numeral 11. As will be described in detail below, protective device 11 is designed primarily to protect a low-voltage circuit to which it is coupled from any potentially harmful, transient, high-voltage electromagnetic energy.

As referenced briefly above, protective device 11 is designed primarily for use in protecting low-voltage circuits from transient electromagnetic energy. In particular, it is envisioned that protective device 11 would be particularly well suited for use in protecting circuits that (i) normally operate at relatively low voltages (e.g., under 50 volts), such as radio receivers, low-voltage control circuits and low-voltage communication circuits, and (ii) operate within a desired frequency range between 1 MHz to 3 GHz or greater.

It has been found that low-voltage circuits of the type described above are rendered susceptible to a wide variety of different destructive energy including, but not limited to, (i) oscillating ring waves with a frequency between 10 kHz and 100 MHz, and (ii) impulses with a rise time of approximately 1 ns or more and a pulse width in the range from 30 ns to 500 microseconds, both types of energy having a peak current that ranges between a few amperes to a few tens of amperes.

For low-voltage circuits connected to a transmission line operating at a frequency range above approximately 10 MHz, it has been found that most of the destructive transient energy falls below the operational frequency band. However, destructive transient energy that falls within the operational frequency band can also be present along the transmission line. Accordingly, as a principal feature of the present invention, device 11 is designed not only to reduce unwanted transient energy that falls beneath the operational frequency band but also limit the magnitude of unwanted transient energy that falls within the operational frequency band without compromising the integrity of any of the desired, or operational, energy.

Protective device 11 comprises a generally enclosed protective casing, or housing, 13 into which is disposed an electrical circuit, or protection circuit, 15. As will be explained further in detail below, the particular design and operation of electrical circuit 15 serves as a principal novel feature of the present invention.

Casing 13 is preferably constructed out of a rigid and durable material, such as metal, and includes a generally rectangular base 17 which is shaped to define a shallow interior cavity 19 dimensioned to receive electrical circuit 15. A flat, rectangular cover, or lid, 21 is mounted onto base 17 so as to enclose cavity 19 and render protective device 11 a unitary component.

Together, base 17 and lid 21 provide casing 13 with a generally rectangular, block-like construction. However, it is to be understood that the shape of base 17 and/or lid 21 could be modified, as deemed necessary, to provide casing 13 with alternative configurations without departing from the spirit of the present invention. For instance, it is envisioned that casing 13 could be alternatively constructed as a generally cylindrical enclosure.

In the present embodiment, a plurality of fastening elements 23, such as screws, are driven transversely through the periphery of cover 21 and into threaded engagement into corresponding bores 25 formed in base 17. However, it should be noted that protective device 11 need not be limited to the use of fastening elements 23 to releasably secure cover 21 onto base 17. Rather, it is to be understood that cover 21 could be mounted onto base 17 using a wide range of different coupling techniques, such as through soldering, welding or press-fit mounting, without departing from the spirit of the present invention.

Additionally, casing 13 is provided with a plurality of mounting holes 27 that extend transversely through both base 17 and cover 21, each mounting hole 27 being preferably located within a corresponding corner of casing 13. In use, mounting holes 27 facilitate securing protective device 11 to an item, such as a fixed electrical panel, and may be internally threaded to receive corresponding mounting screws (not shown).

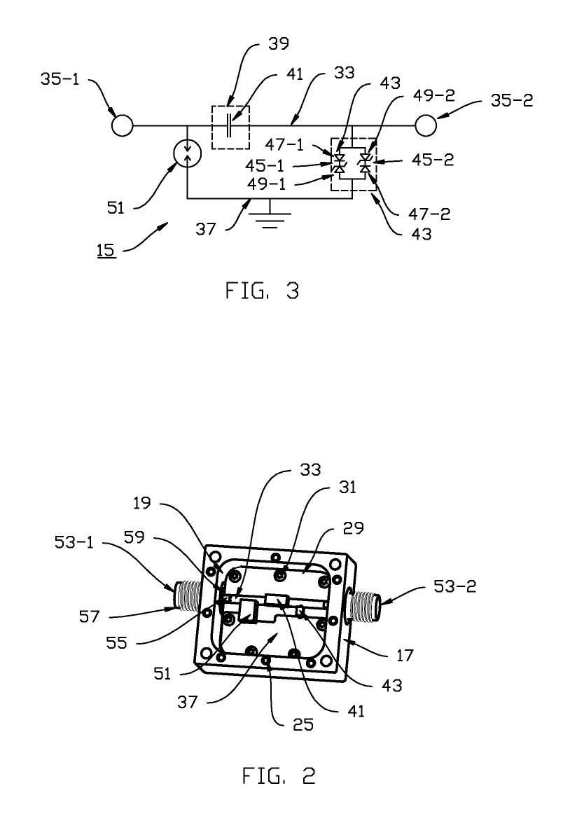

As seen most clearly in FIG. 2, the various electrical components for circuit 15 are preferably mounted on a printed circuit board (PCB) 29 for ease of construction and assembly. Printed circuit board 29, in turn, is fittingly disposed within interior cavity 19 and is permanently secured to base 17 by a plurality of fastening elements 31, such as screws.

Referring now to FIGS. 2 and 3, electrical circuit 15 includes a transmission line, or through path, 33 that extends in electrical communication between an input, or exposed, terminal 35-1 and an output, or treated, terminal 35-2. During routine operation if device 11, transmission line 33 provides a circuit path for passing radio frequency (RF) signals of a designated frequency range between terminals 35-1 and 35-2, with the remainder of circuit 15 provided, inter alia, to treat potentially harmful, high-voltage, transient electromagnetic impulses present in transmission line 33, as will be explained further in detail below.

Transmission line 33 is represented in FIG. 2 as a conductive trace that extends laterally across the width of printed circuit board 29, with the ends of the trace defining input and output terminals 35-1 and 35-2. The particular width of the conductive trace is preferably determined based on the corresponding thickness and dielectric constant of the dielectric layer for PCB 29 to ensure the conductive trace has the proper impedance.

A ground plane 37 is preferably mounted on PCB 29 in a spaced apart relationship relative to the conductive trace that forms transmission line 33. As can be appreciated, ground plane 37 serves as a common ground terminal for various components of electrical circuit 15. Although not shown herein, the opposite surface of PCB 29 (i.e., the side without components that directly abuts against base 25) may additionally include a substantially solid, ground plane mounted thereon, unless features are required to manipulate impedance or to provide additional functionality, as is traditional in microwave microstrip design.

Electrical circuit 15 includes a filter 39 for treating high-voltage, transient electromagnetic impulses that fall primarily below the operational frequency band. In the present embodiment, filter 39 includes a capacitor 41 located in series on transmission line 33 between terminals 35, with one of its terminals connected to input terminal 35-1 and the other of its terminals connected to output terminal 35-2. The aforementioned schematic configuration can be achieved, for example, by conductively connecting capacitor 41 across a gap in the conductive trace that forms transmission line 31.

Preferably, capacitor 41 has a relatively high voltage rating. Optimally, capacitor 41 has a higher voltage rating than highest voltage transient expected. As a result, capacitor 41 would be able to safely handle a transient impulse of any realistic voltage. Furthermore, if any additional component (e.g., a gas discharge tube, quarter-wave stub, or other similar shunting-based protector) is incorporated into electrical circuit 15 to assist capacitor 41 in the treatment of high-voltage transient impulses, the voltage rating of capacitor 41 may be lowered accordingly.

As referenced briefly above, filter 39 operates as a high-pass filter that blocks transient electromagnetic impulses that have frequency content below the filter cut-off frequency. For example, if filter 39 is designed to pass a minimum operational frequency of 30 MHz, any disturbing ring waves (generally with a value at or below approximately 10 MHz) which are received by input terminal 33-1 are attenuated by capacitor 41, thereby protecting the desired low-voltage circuit.

Lower frequency ring wave transients (e.g., of the type described above) tend to produce inversely longer pulse durations. For constant current or voltage input, the energy available in lower frequency pulses is typically higher. However, filter 39 can increase insertion loss at a rate of approximately 40 dB/decade. As a result, device 11 is able to reduce energy at lower frequencies which is adequate to compensate for longer pulse durations.

It should be noted that device 11 is not limited to the particular construction of filter 39. Rather, as will be set forth in detail below, the construction of filter 39 could be modified without departing from the spirit of the present invention. For instance, a higher order filter could be used in place of filter 39 to further attenuate below pass band energy. In fact, any filter with a low frequency block and/or shunt will provide the desired effect of treating transient impulses with energy that falls beneath the operational frequency band.

Electrical circuit 15 additionally includes a semiconductor-based clamping component 43 to limit high-voltage, transient, electromagnetic impulses that fall within the operational frequency band. Clamping component, or voltage limiter, 43 connects transmission line 33, at a location between output terminal 35-2 and capacitor 41, to ground 37.

As defined herein, semi-conductor clamping component 43 represents any silicone or solid-state voltage limiter that preferably has (i) a low capacitance so as not to hinder the highest frequency operation of protective device 11, (e.g., a capacitance of 3.5 pF for operational frequencies up to 500 MHz, a capacitance of 1.0 pF for operational frequencies between 500 MHz and 2.0 GHz, and a capacitance of no greater than 0.5 pF for operational frequencies between 2.0 GHz and 6.0 GHz), (ii) a fast acting time (e.g., less than 1 ns response time), and (iii) low-voltage capabilities (e.g., less than 50 Vdc). Examples of suitable clamping components include, but are not limited to, diode-based components, metal-oxide varistor (MOV)-based components, silicon-controlled rectifier (SCR)-based components, protection thyristor-based components, and triode for alternating current (TRIAC)-based components.

In the present embodiment, semiconductor-based component 43 is represented herein as a diode-based component that includes a first diode array 45-1 in reverse parallel with a second diode array 45-2, as seen most clearly in FIG. 3. Accordingly, the opposite polarity configuration of first and second diode arrays 45-1 and 45-2 provides component 43 with bipolar voltage protection (i.e., protection against both positive and negative polarity voltage transients), which is highly desirable.

First diode array 45-1 includes a rectifier diode 47-1 which is connected in series with a zener diode 49-1 in order to increase the breakover voltage. As can be seen, the positive terminal of rectifier diode 47-1 is connected to transmission line 33 at a location between output terminal 35-2 and capacitor 41, the negative terminal of rectifier diode 47-1 is connected to the negative terminal of zener diode 49-1, and the positive terminal of zener diode 49-1 is connected to ground 37.

Similarly, second diode array 45-2 includes a rectifier diode 47-2 connected in series with a zener diode 49-2 to increase the breakover voltage. As can be seen, the positive terminal of rectifier diode 47-2 is connected to ground 37, the negative terminal of rectifier diode 47-2 is connected to the negative terminal of zener diode 49-2, and the positive terminal of zener diode 49-2 is connected to transmission line 33 at a location between output terminal 35-2 and capacitor 41.

It should be noted that the construction of each diode array 45 could be modified without departing from the spirit of the present invention. For instance, each diode array 45 could consist only of rectifier diode 47, particularly if operational voltages fall below a few hundred millivolts. However, it is to be understood that the utilization of a pair of series diodes for each diode array 45 is preferred in higher frequency applications, as the lower resultant capacitance has a less harmful effect on the desired RF through signal.

The inclusion of voltage-limiting component 43 into electrical circuit 15 provides two notable advantages.

As a first advantage, component 43 limits, or clamps, transient pulses that fall within a predictable, or defined, frequency range. In particular, voltage-limiting component 43 is designed to primarily treat transient energy that falls within the operational frequency band. Transient electromagnetic energy that falls beneath the operational frequency band is treated primarily by filter 39 (based on the particular specifications for filter 39), thereby protecting component 43 from that potentially harmful energy.

As a second advantage, component 43 serves to limit the amount of voltage applied across additional electrical components connected in parallel therewith. For example, alternative configurations of electrical circuit 15 may incorporate an inductor in parallel with component 43, as will be shown in detail below. In this situation, component 43 would limit the voltage across the conductor. As a result, the particular characteristics of the inductor could be selected with less regard to peak voltages, but instead, based on inherent RF properties and size.

Lastly, electrical circuit 15 includes an optional gas discharge tube (GDT) 51 to treat very high electrical current introduced to transmission line 33. As can be seen in FIGS. 2 and 3, GDT 51 connects transmission line 33, at a location between input terminal 35-1 and capacitor 41, to ground 37.

As referenced above, GDT 51 is an optional component that may be incorporated into circuit 15 to increase the ampere capacity, or ampacity, of current diverted to ground 37. Although shown herein as being directly incorporated into electrical circuit 15, it is to be understood that GDT 51 could be located at any position along the signal path in need of overvoltage protection. In fact, when utilized to treat transient currents resulting from lightning strikes, GDT 51 may operate more effectively if located in closer physical proximity to the actual strike (e.g., closer to the entry of the building). In this capacity, lower (i.e., more modest) current threats in need of treatment would be more suitably diverted to either filter 37 or clamping component 39 for handling, rather than GDT 51.

Referring back to FIGS. 1-2, an input connector 53-1 and an output connector 53-2 extend orthogonally out from opposing sides of base 17 and enable circuit 15 to be externally coupled to the signal path in need of protection from transient impulses. In other words, input connector 53-1 is designated to receive an untreated input signal from a signal source. Upon treatment of the input signal by protection circuit 15, the resultant input signal, which has been treated to reduce any undesirable electrical energy associated therewith to an acceptable level, is transmitted to a protected low-voltage circuit via output connector 53-2.

In the present example, each of input connector 53-1 and output connector 53-2 is represented as a standard, press-mount type, SMA jack connector. Accordingly, as seen in FIG. 2, each connector 53 includes a conductive inner pin, or center conductor, 55 that extends coaxially within a conductive outer sleeve 57 and is electrically insulated therefrom by an annular insulator 59. Conductive inner pin 55 for input connector 53-1 is electrically connected to input terminal 35-1 and conductive inner pin 55 for output connector 53-1 is electrically connected to output terminal 35-2, thereby establishing a conductive path between connectors 53-1 and 53-2 via circuit 15.

It should be noted that protective device 11 is not limited to the particular type and arrangement of connectors 53 represented herein. Rather, connectors 53 represent any means for electrically coupling circuit 15 to a signal path in need of overvoltage protection. Accordingly, it is to be understood that the type and arrangement of connectors 53 could be modified without departing from the spirit of the present invention.

### Operation of Protective Device 11

Protective device 11 is designed to pass RF signals of a designated frequency band along a signal path, protective device 11 being disposed at any location along the signal path defined between the signal source and a low-voltage circuit in need of over-voltage protection. As a feature of the present invention, protective device 11 treats any potentially harmful, transient electromagnetic impulses present in signal path, thereby protecting the low-voltage circuit.

To initiate protection, protective device 11 is installed in the signal path between the signal source and the low-voltage circuit. Specifically, an RF cable in electrical connection with the signal source is connected to input connector 53-1. Similarly, an RF cable in electrical connection with the low-voltage circuit in need of over-voltage protection is connected to output connector 53-2. With device 11 installed in the manner set forth above, RF signals within the operational frequency band can be delivered to the low-voltage circuit from the signal source via transmission line 33.

Upon receiving any very high electrical current along the signal path (e.g., as the result of a lightning strike), gas discharge tube 51 suppresses the potentially harmful energy and thereby protects the low-voltage circuit coupled to output terminal 35-2. More modest, transient electromagnetic impulses received along the signal path are preferably treated by either filter 39 or clamping component 43, as will be explained further below.

Specifically, any presence in the signal path of transient electromagnetic impulses that fall beneath the operational frequency band are blocked by capacitor 41 and thereby limited from being carried to either clamping component 43 or output terminal 35-2, which is in turn connected to the low-voltage circuit in need of overvoltage protection. In this manner, by treating the lower frequency transient energy with filter 39, less service is ultimately required of clamping component 41, which is highly desirable.

By contrast, any presence in the signal path of transient electromagnetic impluses that fall within the operational frequency band (i.e., above the pass band frequency of filter 39) are efficiently limited by clamping component 43. Furthermore, as a feature of the invention, the reverse polarity configuration of component 43 provides overvoltage protection against both positive and negative polarity voltage transients.

Because filter 39 operates as a high-pass filter that blocks transient electromagnetic impulses that have frequency content below the filter cut-off frequency, it is to be understood that adjustments to the filter cut-off frequency can be made by simply modifying the performance characteristics of filter 39.

By optimizing the cut-off frequency of filter 39, preferably with ample separation from the pass-band frequency, the size of the various diodes in clamping component 43 that protect output terminal 33-2 from in-band transient energy can be minimized. In particular, voltage-limiting component 43 is specifically rated to treat transient electromagnetic energy that falls within the operational frequency band. As a result, component 43 can be designed using relatively low ampere capacity diodes, which in turn have lower capacitance and thus higher maximum frequency capabilities.

### Additional Embodiments and Design Modifications

It is to be understood that the embodiment described in detail above is intended to be merely exemplary and those skilled in the art shall be able to make numerous variations and modifications without departing from the spirit of the present invention. All such variations and modifications are intended to be within the scope of the present invention as defined in the appended claims.

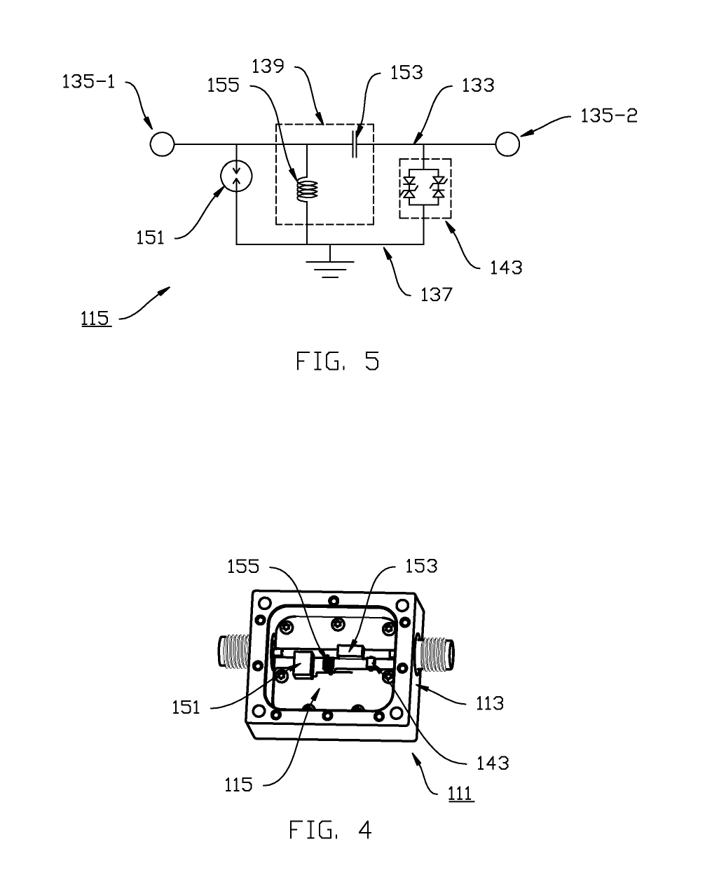

For instance, referring now to FIG. 4, there is shown a front perspective view of a second embodiment of a protective device constructed according to the teachings of the present invention, the protective device being identified generally by reference numeral 111.

As can be seen, protective device 111 is similar to protective device 11 in that protective device 111 includes an enclosed housing, or casing, 113 into which is disposed an electrical circuit 115, with electrical circuit 115 being designed principally to provide overvoltage protection to a low-voltage circuit.

Referring now to FIG. 5, electrical circuit 115 is similar to electrical circuit 15 in that electrical circuit 115 comprises (i) a transmission line, or through path, 133 that extends in electrical communication between an input, or exposed, terminal 135-1 and an output, or treated, terminal 135-2, (ii) a filter 139 for treating high-voltage, transient electromagnetic impulses that fall primarily below the operational frequency band, (iii) a diode-based clamping component 143 to limit high-voltage, transient, electromagnetic impulses that fall within the operational frequency band, and (iv) a gas discharge tube (GDT) 151 to treat very high electrical current introduced to transmission line 133.

Electrical circuit 115 differs from electrical circuit 15 in the construction of filter 139. Specifically, filter 139 is represented herein as a second order L-C filter that includes a capacitor 153 located in series on transmission line 133 between terminals 135-1 and 135-2, and an inductor 155 connecting transmission line 133, at a location between input terminal 135-1 and capacitor 153, to ground 137.

During normal operation of electrical circuit 115, the desired operational frequencies pass though filter 139 with minimal attenuation. The disturbing electrical energy present along the signal path that falls beneath the operational frequency range is blocked by series capacitor 153 and is conducted directly to ground 137 via inductor 155, thereby preventing the energy from being carried to clamping component 143 or output terminal 135-2. Furthermore, it should be noted that the inclusion of inductor 155 enables capacitor 153 to be more limited in voltage rating in many applications.

Additionally, inductor 155 serves to share any transient current shunted by GDT 151, since inductor 155 and GDT 151 are connected in parallel. Sharing of the transient current by inductor 155 can increase the life of GDT 151 in the application.

### Optimization of GDT Performance Using Inductive Beads

It has been found that the incorporation of gas discharge tubes into protective circuits (e.g., circuit 115) introduces a notable performance shortcoming, which will be explained in detail below. For illustrative purposes only, the shortcoming will be explained in connection with electrical circuit 115. However, it is to be understood that the performance shortcoming to be explained below is not limited to electrical circuit 115, but rather, is prevalent in various types of protective circuits that rely upon gas discharge tubes for treating unwanted transient energy.

Referring now to FIG. 5, gas discharge tube 151 functions to reduce the peak energy of disturbing transient pulses received at input terminal 135-1, which is highly desirable. GDT 151, as is the case with most conventional gas discharge tubes, is designed to ultimately clamp at a relatively low voltage level. However, it has been found that during the process of reducing the peak energy of disturbing transient pulses, gas discharge tubes often add frequency content to the reduced voltage output waveform. In other words, the resultant, or treated, transient energy received at output terminal 135-2 in response to operation of gas discharge tube 151 has a significantly lower peak voltage level but is often shifted into a different frequency range.

In fact, it has been found that the output waveform generated in response to activation of GDT 151 has a frequency that is shifted into the operational frequency band, particularly into the bands from 10 MHz to 1 GHz. Although electric circuit 115 is designed to handle unwanted transient energy that is shifted into the operational frequency band, it is nonetheless desirable to prevent signal content from being shifted into the operational frequency band for performance optimization purposes (e.g., to limit interference between the wanted and unwanted signal components). Higher order filters or band pass filters may be employed to achieve even more dramatic energy blocking, as will be illustrated in subsequent embodiments.

It has been found that the shift in signal content caused by operation of gas discharge tube 151 is largely the result of its short fall time when a GDT changes to the conductive state in response to a high voltage. Accordingly, by incorporating a component with a specific type of inductive and resistive impedance in series with GDT 151, the output pulse generated in response to activation of GDT 151 will have a longer fall time. Consequently, by managing the fall time of GDT 151, a reduction in the frequency shift of the remaining energy can be achieved, thereby maintaining the energy content closer to the original, lower frequency level, which is highly desirable.

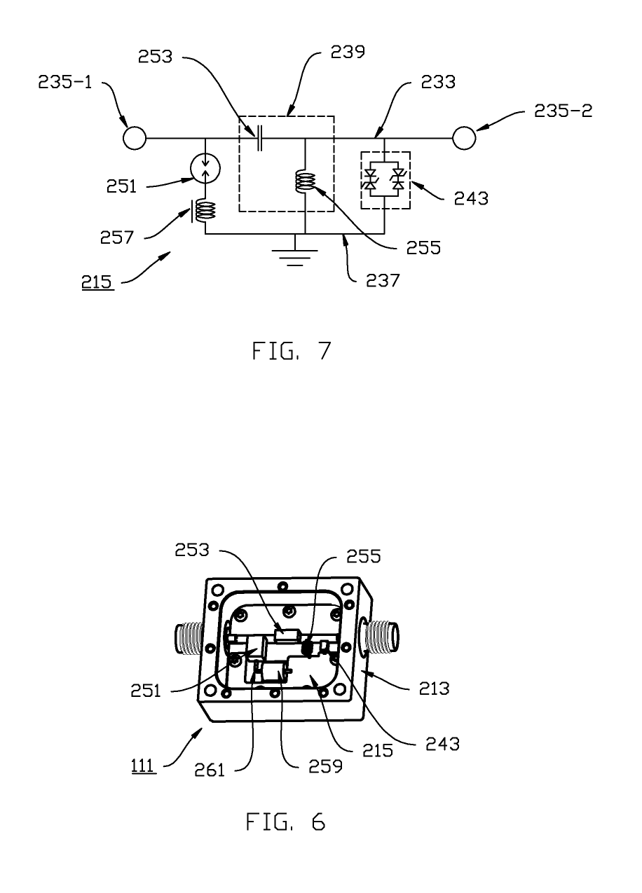

For instance, referring now to FIG. 6, there is shown a third embodiment of a protective device constructed according to the teachings of the present invention, the protective device being identified generally by reference numeral 211.

As can be seen, protective device 211 is similar to protective device 111 in that protective device 211 includes an enclosed housing, or casing, 213 into which is disposed an electrical circuit 215, with electrical circuit 215 being designed principally to provide overvoltage protection to a low-voltage circuit.

Referring now to FIG. 7, electrical circuit 215 is similar to electrical circuit 115 in that electrical circuit 215 comprises (i) a transmission line, or through path, 233 that extends in electrical communication between an input, or exposed, terminal 235-1 and an output, or treated, terminal 235-2, (ii) a filter 239 for treating high-voltage, transient electromagnetic impulses that fall primarily below the operational frequency band, (iii) a diode-based clamping component 243 to limit high-voltage, transient, electromagnetic impulses that fall within the operational frequency band, and (iv) a gas discharge tube (GDT) 251 to treat very high electrical current introduced to transmission line 233.

Electrical circuit 215 differs from electrical circuit 115 in the construction of filter 239. Specifically, filter 239 includes a capacitor 253 located in series on transmission line 133 between terminals 235-1 and 235-2, and an inductor 255 connecting transmission line 233 to ground 237. However, it should be noted that inductor 255 is connected to transmission line 233 at a location between capacitor 253 and output terminal 235-2, rather than between capacitor 253 and input terminal 235-1, so as to form a C-L low pass filter.

More significantly, electrical circuit 215 differs from electrical circuit 115 in that electrical circuit 215 includes an inductive component 257 in series with gas discharge tube 251, with inductive component 257 being located between GDT 251 and ground 237.

It should be noted that the inclusion of inductive component 257 runs counterintuitive to traditional circuit design, since the inductance, or impedance, of component 257 could limit the shunting capability of GDT 251. However, as will be explained further below, inductive component 257 is preferably constructed of a material that (i) does not compromise either the performance or response time of GDT 251, and (ii) increases the fall time of the treated transient energy.

Specifically, inductive component 257 is preferably constructed, at least in part, of a ferrite material. For instance, component 257 may be constructed using a nickel-zinc (NiZn) ferrite material currently available for sale by Fair-Rite Products Corp., of Willkill, N.Y., under the brand name 43 Material.

As can be appreciated, ferrite material exhibits two principal characteristics which are particular significance, namely, (i) the ferrite material functions as an inductive element when conducting signals of lower frequencies and, in turn, transitions to a resistive element with a nearly constant resistance when conducting signals of higher frequencies, and (ii) the ferrite material is a high permeability material, which in turn causes high current to saturate the core and thereby reduce inductance to a conductive element passed therethrough, such as a wire.

In the present embodiment, inductive component 257 comprises an annular ferrite bead 259 through which a wire 261 is fittingly passed in coaxial alignment therewith, as seen in FIG. 6. The free ends of wire 261 are connected to GDT 251 and ground 237, as shown in FIG. 7, thereby rendering component 257 in series with GDT 251. However, although not shown herein, it is to be understood that ferrite bead 259 could be alternatively mounted directly on a conductive lead for GDT 251, thereby eliminating the need for wire 261 entirely.

In use, inductive component 257 interacts with GDT 251 in the following manner. Specifically, prior to the activation (i.e., shunting) of GDT 251, any impulse voltage received at input terminal 235-1 is impressed substantially across GDT 251 due to its relatively high resistance. At the same time, any voltage generated across ferrite bead 259 from the input pulse is negligible, and does not interfere with GDT 251 initiating its short circuit shunting operation.

Upon initiation of activation by GDT 251, the initial current flow associated with the transient energy is impressed across GDT 251 due to its resistive impedance. As a result, the fixed resistance of ferrite bead 259 would not produce an unlimited voltage drop, as an inductor would. Consequently, the increase in the total voltage across both GDT 251 and ferrite bead 259 would be adequately managed upon initial shunting of GDT 251.

As current continues to flow to shunted GDT 251, the impedance of ferrite bead 259 drops because (i) the frequency content for longer duration pulses is lower, and thus the impedance of bead 259 drops accordingly due to its inherent operational characteristics, and (ii) the increase in current saturates the ferrite material for bead 259, and thus lowers its impedance. Ultimately, at very high currents, the only inductance exhibited by component 257 is the self-inductance of wire 261. As a result, ferrite bead 259 does not dramatically increase voltage drop at high currents.

As noted briefly above, the characteristics exhibited by ferrite bead 259 in response to the activation of GDT 251 serve to preserve the initial rise time of the treated transient energy, and then, extend the fall time of the treated transient energy. This slowing of the fall time has the effect of dramatically shifting the frequency content of the output waveform to lower frequencies (i.e., frequencies beneath the operational frequency), which can therefore be blocked using common filtering techniques (e.g., by series capacitor 253, which is connected to transmission line 233 after GDT 251).

For the most efficient operation of inductive component 257, the inductive voltage of ferrite bead 259 should be selected based on the characteristics of gas discharge tube 251. In particular, the inductive voltage of ferrite bead 259 selected for use in circuit 215 should be approximately the same, or somewhat less than, the peak voltage for GDT 251.

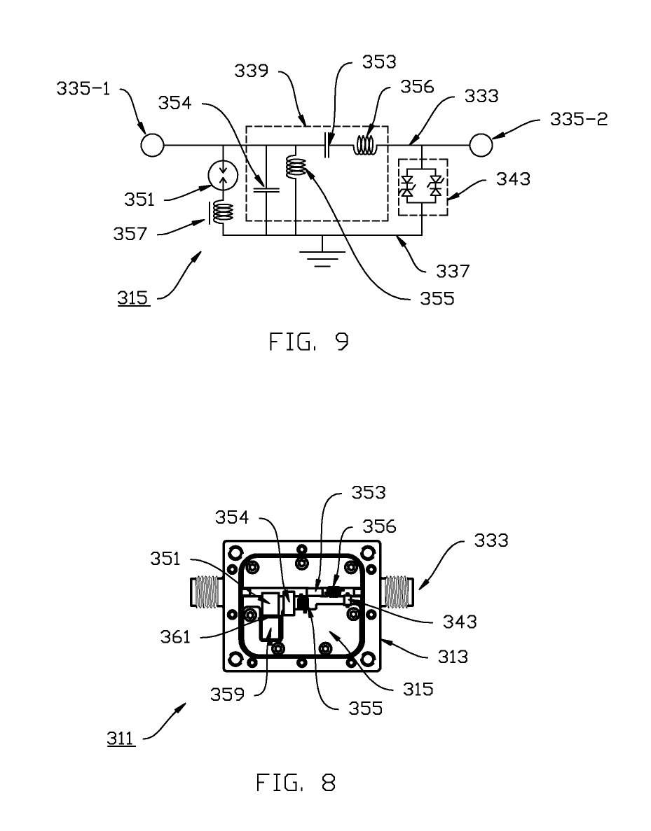

Referring now to FIG. 8, there is shown a third embodiment of a protective device constructed according to the teachings of the present invention, the protective device being identified generally by reference numeral 311.

As can be seen, protective device 311 is similar to protective device 211 in that protective device 311 includes an enclosed housing, or casing, 313 into which is disposed an electrical circuit 315, with electrical circuit 315 being designed principally to provide overvoltage protection to a low-voltage circuit.

Referring now to FIG. 9, electrical circuit 315 is similar to electrical circuit 215 in that electrical circuit 315 comprises (i) a transmission line, or through path, 333 that extends in electrical communication between an input, or exposed, terminal 335-1 and an output, or treated, terminal 335-2, (ii) a filter 339 for treating high-voltage, transient electromagnetic impulses that fall primarily below the operational frequency band, (iii) a diode-based clamping component 343 to limit high-voltage, transient, electromagnetic impulses that fall within the operational frequency band, and (iv) a gas discharge tube (GDT) 351 connected in series with an inductive component 357 to treat very high electrical current introduced to transmission line 333, inductive component 357 comprising an annular ferrite bead 359 through which a wire 361 is fittingly passed in coaxial alignment therewith, as seen in FIG. 8.

Electrical circuit 315 differs from electrical circuit 215 in the construction of filter 339. Specifically, filter 339 is provided with enhanced signal filtering capabilities and includes (i) a first capacitor 353 located in series on transmission line 333 between terminals 335-1 and 335-2, (ii) a second capacitor 354 connected between transmission line 333, at a location between capacitor 353 and input terminal 335-1, and ground 357, (iii) a first inductor 355 connected in parallel with second capacitor 354 (i.e., connected between transmission line 333, at a location between capacitor 353 and input terminal 335-1, and ground 357), and (iv) a second inductor 356 located in series on transmission line 333 between first capacitor 353 and second terminal 335-2. As can be seen, filter 339 is a second order band pass filter, with the pass band selected according to the operational bandwidth.

As referenced briefly above, each of clamping components 43, 143, 243 and 343 need not be limited to a diode-based component. Rather, it is to be understood that each of clamping components 43, 143, 243 and 343 could be in the form of a metal-oxide varistor (MOV)-based component, a silicon-controlled rectifier (SCR)-based component, a protection thyristor-based component, or a triode for alternating current (TRIAC)-based component, all of which are silicone or solid-state voltage limiters with low capacitance so as not to hinder the highest frequency operation of the protective device in which it is incorporated (e.g., a component with a capacitance of 3.5 pF for operational frequencies up to 500 MHz, a capacitance of 1.0 pF for operational frequencies between 500 MHz and 2.0 GHz, and a capacitance of no greater than 0.5 pF for operational frequencies between 2.0 GHz and 6.0 GHz). In particular, each of clamping components 43, 143, 243 and 343 preferably represents any clamping component that is characterized as having a fast acting time (e.g., less than 1 ns response time) and low-voltage capabilities (e.g., less than 50 Vdc).

What is claimed is:

1. A protective device for transmitting electromagnetic signals of an operational frequency band, the protective device comprising:
(a) a transmission line connecting an input terminal to an output terminal;
(b) a filter for blocking any transient electromagnetic energy received by the transmission line that has a frequency that falls below the operational frequency band, the filter comprising a capacitor located in series on the transmission line between the input terminal and the output terminal; and
(c) a semiconductor-based clamping component for limiting any transient electromagnetic energy received at the input terminal that has a frequency that falls within the operational frequency band, the semiconductor-based clamping component connecting the transmission line to a ground terminal, the semiconductor-based clamping component being connected to the transmission between the capacitor and the output terminal.

2. The protective device as claimed in claim 1 wherein the semiconductor-based clamping component comprises a first diode array.

3. The protective device as claimed in claim 2 wherein the first diode array includes a rectifier diode connected in series with a zener diode.

4. The protective device as claimed in claim 3 wherein the semiconductor-based clamping component comprises a second diode array connected in reverse parallel with the first diode array.

5. The protective device as claimed in claim 4 wherein the second diode array includes a rectifier diode connected in series with a zener diode.

6. The protective device as claimed in claim 1 further comprising an inductor connected in series with the capacitor, the inductor being located between the input terminal and the semiconductor-based clamping component.

7. The protective device as claimed in claim 6 wherein the inductor is connected to the transmission line between the input terminal and the capacitor.

8. The protective device as claimed in claim 1 further comprising a gas discharge tube connecting the transmission line to the ground terminal, the gas discharge tube being connected to the transmission line between the input terminal and the capacitor.

9. The protective device as claimed in claim 8 further comprising an inductive component connected in series with the gas discharge tube.

10. The protective device as claimed in claim 9 wherein at least a portion of the inductive component is constructed of a ferrite material.

11. The protective device as claimed in claim 10 wherein the inductive component comprises at least one ferrite bead.

12. The protective device as claimed in claim 10 wherein the inductive component comprises an annular ferrite bead through which a wire is fittingly passed in coaxial alignment therewith.

13. A protective device for transmitting electromagnetic signals of an operational frequency band, the protective device comprising:
(a) a transmission line connecting an input terminal to an output terminal;
(b) a gas discharge tube for connecting the transmission line to a ground terminal; and
(c) an inductive component connected in series with the gas discharge tube, the inductive component being located between the gas discharge tube and the ground terminal.

14. The protective device as claimed in claim 13 wherein at least a portion of the inductive component is constructed of a ferrite material.

15. The protective device as claimed in claim 14 wherein the inductive component comprises at least one ferrite bead.

16. The protective device as claimed in claim 15 wherein the inductive component comprises an annular ferrite bead through which a wire is fittingly passed in coaxial alignment therewith.
